(19) United States
(12) Patent Application Publication
(10) Pub. No.: US 2026/0013376 A1
(43) Pub. Date: Jan. 8, 2026

(54) DISPLAY DEVICE AND ELECTRONIC DEVICE

(71) Applicant: Samsung Display Co., Ltd., Yongin-Si (KR)

(72) Inventors: YONG-HOON YANG, Yongin-si (KR); HEEKYUN SHIN, Yongin-si (KR); JUNHO SIM, Yongin-si (KR)

(21) Appl. No.: 19/074,440

(22) Filed: Mar. 10, 2025

(30) Foreign Application Priority Data
Jul. 2, 2024 (KR) 10-2024-0086663

(51) Int. Cl. H10K 59/80; H10K 59/65; H10K 102/00

(52) U.S. Cl. CPC H10K 59/8731; H10K 59/65; H10K 2102/351

(57) ABSTRACT

An electronic device includes a first organic layer and a first barrier layer and a second organic layer and a second barrier layer and a circuit layer and a light emitting layer and an encapsulation layer. The first barrier layer is disposed on the first organic layer, the second organic layer is disposed on the first barrier layer, and the second barrier layer is disposed on the second organic layer. The electronic device includes a portion where the first barrier layer and the second barrier layer make contact. The circuit layer is disposed on the second barrier layer. The light emitting layer is disposed on the circuit layer. The encapsulation layer is disposed on the light emitting layer.

### CROSS-REFERENCE TO RELATED APPLICATIONS

This application claims priority to and benefits, under 35 U.S.C § 119, of Korean Patent Application No. 10-2024-0086663 filed on Jul. 2, 2024 in the Korean Intellectual Property Office, the contents of which are incorporated herein in its entirety by reference.

### BACKGROUND

### 1. Technical Field

The present disclosure relates to a display device. Specifically, the present disclosure relates to a display device having an improved durability by preventing external moisture or oxygen from entering the device.

### 2. Description of the Related Art

A display device may be sectioned into a display area where an image is displayed, and a non-display area. Wide screen display devices are popular because their increased screen width makes it easier to draw and hold a user's attention and effectively achieve the desired aesthetic impression. Accordingly, various techniques for implementing a full screen are drawing attention, including UPC (Under Panel Camera).

The UPC (Under Panel Camera) is a technique of having a camera module disposed under a display device panel. A display device may include a structure in which an organic layer including an organic material and an inorganic layer including an inorganic material are alternately laminated. When a user is not using a camera function, an image should be reproduced on the display device, and when the user is using the camera function, a camera module should detect light. To that end, the camera module often incorporates a highly transmissive, transparent organic layer for better detection of light.

However, when cell-cut is performed during the manufacturing process, peeling occurs between the highly transmissive, transparent organic layer and the inorganic layer, leading to penetration of moisture and oxygen through a side interface between the organic layer and the inorganic layer.

### SUMMARY

The present disclosure aims to provide a highly durable display device by preventing any peeling between an organic layer and an inorganic layer.

A display device according to an embodiment of the present disclosure may include a first organic layer, a first barrier layer, a second organic layer, a second barrier layer, a circuit layer, a light-emitting layer and an encapsulation layer. The first barrier layer may include an inorganic material and be disposed on the first organic layer. The second organic layer may include an organic material and be disposed on the first barrier layer. The second barrier layer may include an inorganic material and be disposed on the second organic layer. The circuit layer may include a plurality of transistors and be disposed on the second barrier layer. The light-emitting layer may include a plurality of light-emitting diodes and be disposed on the circuit layer. The encapsulation layer may be disposed on the light-emitting layer. One portion of the first barrier layer may make contact with one portion of the second barrier layer.

According to an embodiment of the present disclosure, the circuit layer, the light-emitting layer, and the encapsulation layer may not overlap with the one portion of the first barrier layer.

According to an embodiment of the present disclosure, each of the first organic layer and the second organic layer may be configured to transmit at least some of incident light.

According to an embodiment of the present disclosure, at least 70% of blue light having a wavelength of 450 nm that is incident on the second barrier layer is transmitted through the first organic layer.

The display device according to an embodiment of the present disclosure may include a camera module. The camera module may be disposed under the first organic layer, have one portion overlapped with at least one of the plurality of light-emitting diodes, and be configured to detect light having penetrated through at least one of the first organic layer and the second organic layer.

According to an embodiment of the present disclosure, a thickness of the one portion of the first barrier layer may be smaller than a thickness of another portion of the first barrier layer.

According to an embodiment of the present disclosure, the one portion of the second barrier layer may make contact with the one portion of the first organic layer.

According to an embodiment of the present disclosure, a thickness of the one portion of the first organic layer may be smaller than a thickness of another portion of the first organic layer.

According to an embodiment of the present disclosure, a portion adjacent to the one portion of the second barrier layer may be bent.

According to an embodiment of the present disclosure, the one portion of the second barrier layer may overlap with another portion of the second barrier layer.

The display panel may include a first organic layer, a first barrier layer, a second organic layer and a second barrier layer. The display panel may be defined with a display area configured to display an image and a non-display area surrounding the display area. The first organic layer may include an organic material. The first barrier layer may be disposed on the first organic layer and include an inorganic material. The second organic layer may be disposed on the first barrier layer and include an organic material. The second barrier layer may cover the second organic layer and include an inorganic material. A portion of the second barrier layer corresponding to the non-display area may make contact with the first barrier layer. The plurality of transistors may be disposed on the second barrier layer. The plurality of light-emitting diodes may be electrically connected with the plurality of transistors.

In the display device according to an embodiment of the present disclosure, an area of the first organic layer may be greater than an area of the second organic layer.

According to an embodiment of the present disclosure, each of the first organic layer and the second organic layer may be configured to transmit at least some of incident light.

In an embodiment of the present disclosure, each of the first organic layer and the second organic layer may include a material represented by the following Formula 1:

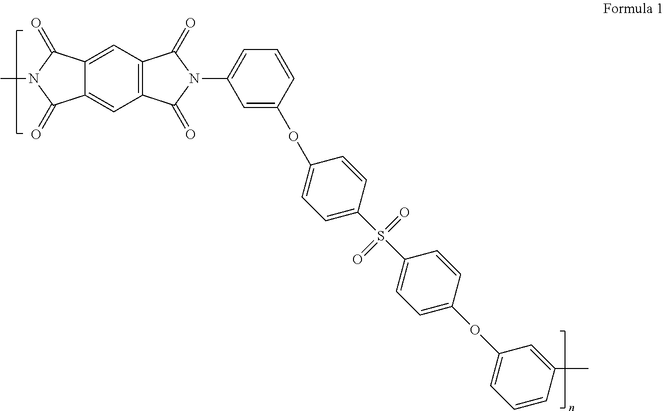

The display device according to an embodiment of the present disclosure may include a camera module. The camera module may overlap with the first organic layer and may be configured to detect light that has passed through at least one of the first organic layer and the second organic layer.

In an embodiment of the present disclosure, a thickness of a portion of the first barrier layer contacting the second barrier layer may be smaller than a thickness of another portion of the first barrier layer.

In an embodiment of the present disclosure, the portion of the second barrier layer that corresponds to the non-display area may make contact with the one portion of the first organic layer.

In an embodiment of the present disclosure, a thickness of a portion of the first organic layer corresponding to the non-display area may be smaller than a thickness of a portion of the first organic layer corresponding to the display area.

In an embodiment of the present disclosure, a portion of the second barrier layer adjacent to the portion of the second barrier layer that makes contact with the first barrier layer may be bent, and the portion of the second barrier layer making contact with the first barrier layer may overlap with another portion of the second barrier layer

An electronic device according to an embodiment of the present disclosure may include a first organic layer, a first barrier layer, a second organic layer, a second barrier layer, a circuit layer, a light-emitting layer and an encapsulation layer. The first organic layer may include an organic material. The first barrier layer may be disposed on the first organic layer and include an inorganic material. The second organic layer may be disposed on the first barrier layer and include an organic material. The second barrier layer may be disposed on the second organic layer and include an inorganic material. One portion of the second barrier layer may make contact with one portion of the first barrier layer. The circuit layer may be disposed on the second barrier layer and include a plurality of transistors. The light-emitting layer may be disposed on the circuit layer and include a plurality of light-emitting diodes. The encapsulation layer may be disposed on the light-emitting layer. A thickness of the one portion of the first barrier layer may be smaller than a thickness of another portion of the first barrier layer that is not making contact with the second barrier layer.

According to an embodiment of the present disclosure, it is possible to provide a display device with a strong barrier that prevents moisture and oxygen from entering, by preventing peeling between an organic layer and an inorganic layer.

In addition, it is possible to dispose a camera module under the display device panel, using a highly transmissive, transparent organic layer, thereby enabling a camera area to operate as a display area, resulting in a full-screen display device.

### BRIEF DESCRIPTION OF THE DRAWINGS

These and/or other features will become apparent and more readily appreciated from the following description of the embodiments, taken in conjunction with the accompanying drawings in which:

FIG. 1 is a perspective view of a display device according to an embodiment of the present disclosure;

Each of FIGS. 2A, 2B, 2C and 2D is a cross-sectional view of the display device according to an embodiment of the present disclosure;

FIG. 3 is a plan view of the display panel according to an embodiment of the present disclosure;

FIG. 4 illustrates an equivalent circuit of a pixel according to an embodiment of the present disclosure;

FIG. 5 is an exemplary illustration of signals applied to the pixel shown in FIG. 4;

FIG. 6 is a cross-sectional view illustrating a portion of a pixel according to an embodiment of the present disclosure;

FIG. 7A is a magnified view of a portion of the camera area shown in FIG. 1;

FIG. 7B is a cross-sectional view of the camera area shown in FIG. 1;

FIG. 8 is a graph illustrating transmissivity per wavelength of light penetrating a set of layers according to an embodiment of the present disclosure;

FIG. 9A is an exemplary illustration of a portion of a cross-section taken along the I-I′ line of FIG. 1;

FIG. 9B is an exemplary illustration of a portion of a cross-section taken along the II-II′ line of FIG. 1;

FIG. 10 is an exemplary illustration of a portion of a cross-section taken along the I-I′ of FIG. 1 in accordance with another embodiment of the present disclosure;

FIG. 11A is an exemplary illustration of a portion of a cross-section taken along the I-I′ of FIG. 1 in accordance with yet another embodiment of the present disclosure;

FIG. 11B is a magnified view of a portion marked with BBA in FIG. 11A;

FIG. 12 is an exemplary illustration of a portion of a cross-section taken along the I-I′ of FIG. 1 in accordance with still another embodiment of the present disclosure;

FIG. 13 is an exemplary illustration of a portion of a cross-section taken along the I-I′ of FIG. 1 in accordance with still yet another embodiment of the present disclosure; and

FIGS. 14 through 20D are exemplary illustration of processes involved in a method of preparing a display panel according to an embodiment of the present disclosure.

FIG. 21 is an exemplary block diagram of an electronic device according to an embodiment.

FIG. 22 illustrates schematic diagrams of electronic devices according to different embodiments.

### DETAILED DESCRIPTION

References will now be made in detail to certain embodiments, of which examples are illustrated in the accompanying drawings, where like reference numerals refer to like elements throughout. The embodiments may have a variety of forms and permutations, but the present disclosure shall by no means be construed as being limited to the described embodiments. Rather, the present disclosure shall be construed to encompass all forms, permutations, equivalents and substitutes covered by the technical ideas and scope of the present disclosure. Accordingly, the embodiments are merely described below, by referring to the figures, to explain features of the present disclosure.

In the accompanying drawings, ratios and dimensions of the elements may not be to exact scale and may have been exaggerated for the benefit of effective explanation of the technical features associated with these elements. Any reference to “and/or” shall be construed to include one or more combinations that can be defined by relevant elements.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof. As used herein, “exemplary” is used as an adjective form of “example,” and does not indicate any preference of embodiments.

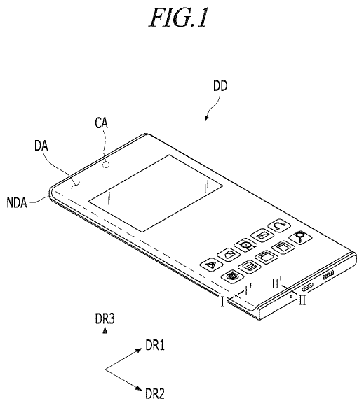

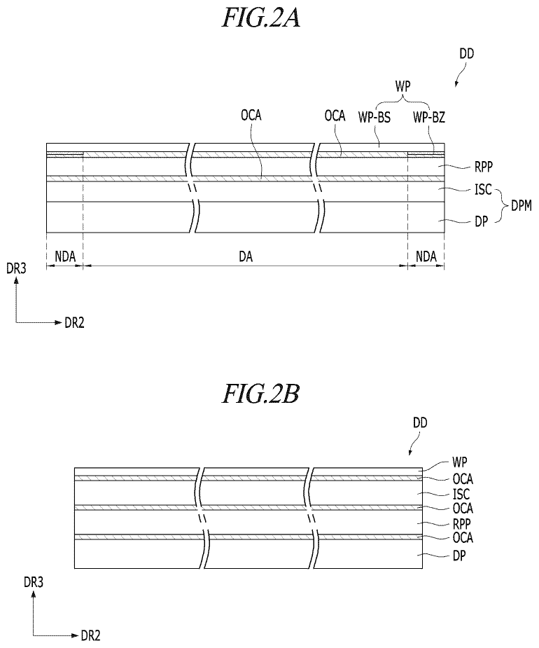

FIG. 1 is a perspective view of a display device DD according to an embodiment of the present disclosure.

FIG. 1 is an exemplary illustration in which a smartphone is a display device DD. Yet, the present disclosure is not limited to what is illustrated in FIG. 1, and the display device DD may be not only a large electronic device, such as a television, a monitor, or an electronic display board, but also a small or medium size electronic device, such as a tablet, a built-in display of a home appliance, or a smart watch.

A display device DD may be defined with a display area DA and a non-display area NDA.

The display area for displaying an image is parallel to a plane defined by a first directional axis DR1 and a second directional axis DR2. A normal direction of the display area DA, i.e. a direction of a thickness of the display device DD is defined by a third directional axis DR3. A front surface (or an upper surface) and a back surface (or a lower surface) is distinguished by the third directional axis DR3. However, directions pointed by the first through the third directional axes are merely a relative concept and may be converted into other directions. Hereinafter, the first through the third directions are directions pointed by the first through the third directional axes, respectively, and described with the same figure references. A shape of the display area DA illustrated in FIG. 1 as an example may be modified without limitation as necessary. The non-display area NDA is an area adjacent to the display area DA that does not display an image. A bezel area of the display device DD may be defined by the non-display 20 area NDA. The display area DA may be surrounded by the non-display area NDA. Yet, the shapes of the display area DA and the non-display area NDA are not limited to the above configurations and may be modified.

A camera area CA of FIG. 1 may be in the display area DA. When a user is not using the camera function, an image may be reproduced in the camera area CA. When the user is using the camera function, it is possible to take a photograph via the camera area CA.

FIGS. 2A through 2D are cross-sectional views of a display device DD according to an embodiment of the present disclosure.

FIGS. 2A through 2D illustrate a cross-section defined by the second directional axis DR2 and the third directional axis DR3. FIGS. 2A through 2D are simplified to describe laminated relationships among functional panels and/or functional members composing the display device DD.

As illustrated in FIG. 2A, the display device DD may include a display panel DP, an input sensor circuit ISC, a reflection protection plate RPP, and a window plate WP. The input sensor circuit ISC may be directly disposed on the display panel DP. When an element is “directly disposed on” another element, it is intended to mean that there is no other adhesive layer/adhesive member interposed therebetween.

A display module DPM may be defined to include the display panel DP and the input sensor circuit ISC directly disposed on the display panel DP. An optically clear adhesive member OCA is interposed between the display module DPM and the reflection protection plate RPP and between the reflection protection plate RPP and the window panel WP, respectively.

The display panel DP reproduces an image, and the input sensor circuit ISC obtains a coordination information of the external input (e.g., microcurrent or applied pressure). Although not illustrated, the display module DPM according to an embodiment of the present disclosure may further include a protective plate disposed below the display panel DP. The protective plate and the display panel DP may be coupled by an adhesive member. Display devices DD of FIGS. 2B through 2D described hereinafter may also further include a protective member.

The display panel DP according to an embodiment of the present disclosure may be a light-emitting display panel. For example, a display panel DP may be an organic light-emitting display panel, a quantum dot light-emitting display panel, or a micro light-emitting display panel. A light-emitting layer of an organic light-emitting display panel may include an organic light-emitting material. An inorganic light-emitting display panel composed of an inorganic material may include a quantum dot light-emitting display panel and a micro light-emitting display panel. Hereinafter, the display panel DP is described as an organic light-emitting display panel.

The reflection protection plate RPP reduces the amount of reflection of an external light incident on an upper side of the window plate WP. The reflection protection plate RPP according to an embodiment of the present disclosure may include a retarder and a polarizer.

The reflection protection plate RPP according to an embodiment of the present disclosure may include color-filters.

The window plate WP according to an embodiment of the present disclosure includes a base film WP-BS and a light-blocking pattern WP-BZ. The base film WP-BS may include glass and/or a synthetic resin. The base film WP-BS is not limited to a single layer. The base film WP-BS may include two or more films coupled by an adhesive member.

The light-blocking pattern WP-BZ partially overlaps with the base film WP-BS. The light-blocking pattern WP-BZ may be disposed below the base film WP-BS to define the bezel area, i.e. the non-display area NDA, of the display device DD.

Hereinafter, the light blocking pattern WP-BZ and the base film WP-BS are not illustrated in FIGS. 2B through 2D.

As illustrated in FIG. 2B, the display device DD may include a display panel DP, a reflection protection plate RPP, an input sensor circuit ISC, and a window plate WP.

The display panel DP and the reflection protection plate RPP may be coupled by an optically clear adhesively bonded components OCA. The reflection protection plate RPP and the input sensor circuit ISC may be coupled by an optically clear adhesively bonded components OCA. The input sensor circuit ISC and the window plate WP may be coupled by an optically clear adhesively bonded components OCA.

The embodiment of FIG. 2C differs from the embodiment of FIG. 2B in the positions of the reflection protection plate RPP and the input sensor circuit ISC are switched.

In the embodiment of FIG. 2D, adhesively bonded components OCA are omitted from the display device DD, and the display panel DP, the input sensor circuit ISC, the reflection protection plate RPP, and the window plate WP may be sequentially laminated. In another embodiment of the present disclosure, the lamination order of the input sensor circuit ISC and the reflection protection plate RPP may be switched.

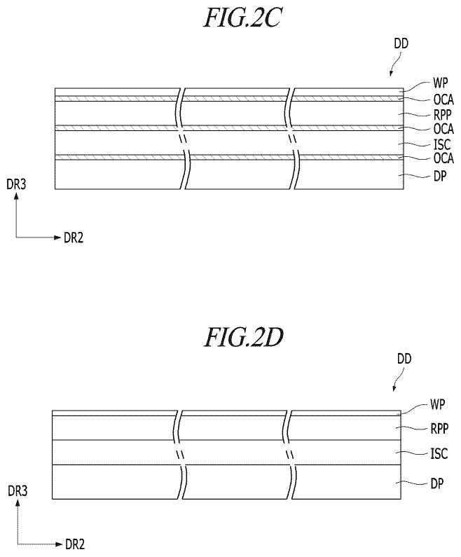

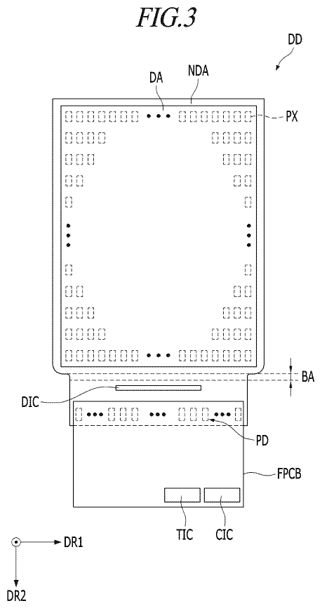

FIG. 3 is a plan view of the display panel DP according to an embodiment of the present disclosure.

A display area DA and a non-display area NDA may be defined in a display panel DP. The non-display area NDA may be defined along the surrounding of the display area DA. The display area DA and the non-display area NDA of the display panel DP may respectively correspond to the display area DA and the non-display area NDA of the display device of FIG. 1.

The display panel DP may include a plurality of pixels PX, a data driving integrated circuit DIC, a plurality of pads PD, a flexible printed circuit board FPCB, a touch-sensor integrated circuit TIC, and a control integrated circuit CIC.

The data driving integrated circuit DIC may be electronically connected to the pixels PX of the display area DA to provide a data signal to the pixels PX.

The touch-sensor integrated circuit TIC and the control integrated circuit CIC may be mounted on the flexible printed circuit board FPCB and configured to receive an electronic signal from the plurality of pads PD.

The touch-sensor integrated circuit TIC may use the plurality of pads PD to process a signal indicating a change of current applied to the display area DA due to a user's touch or a signal indicating an applied external pressure via the input sensor circuit ISC.

The control integrated circuit CIC may be a circuit configured to control at least one of the data driving integrated circuit DIC and the touch-sensor integrated circuit TIC.

A bending area BA of the display panel DP may be bent.

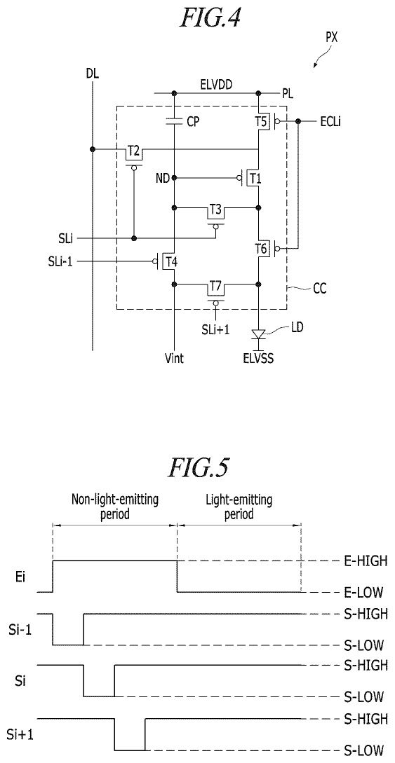

FIG. 4 illustrates an equivalent circuit of a pixel PX according to an embodiment of the present disclosure. FIG. 5 is an exemplary illustration of a light-emitting control signal Ei and scan signals Si−1, Si and Si+1 applied to the pixel PX of FIG. 4. FIG. 4 is an exemplary illustration of the pixel PX connected to an i-th scan line SLi and an i-th light-emitting control line ECLi.

The pixel PX may include a light-emitting diode LD and a pixel circuit CC.

An organic light-emitting diode OLED is exemplarily described as a light-emitting diode LD.

The pixel circuit CC may include a plurality of transistors T1 to T7 and a capacitor CP. The pixel circuit CC controls an amount of current flowing through the light-emitting diode LD in response to a data signal.

The light-emitting diode LD may emit light with a predetermined luminance corresponding to the amount of current provided from the pixel circuit CC. To that end, a level of a first power ELVDD may be set higher than a level of a second power ELVSS.

Each of the plurality of transistors T1 to T7 may include an input electrode (or a source electrode), an output electrode (or a drain electrode), and a control electrode (or a gate electrode). In the present disclosure, for convenience, one of the input electrode and the output electrode may be referred to as a first electrode, and the other may be referred to as a second electrode.

The first electrode of the first transistor T1 is connected to the first power ELVDD via the fifth transistor T5, and the second electrode is connected to the anode electrode of the light-emitting diode LD via the sixth transistor T6. The first transistor T1 may be referred to as a driving transistor in this specification.

The first transistor T1 is configured to control the amount of current flowing through the light-emitting diode LD in response to a voltage applied to the control electrode.

The second transistor T2 is connected between the data line DL and the first electrode of the first transistor T1. In addition, the control electrode of the second transistor T2 is connected to the i-th scan line SLi. When the i-th scan signal Si is provided to the i-th scan line SLi, the second transistor T2 is turned on to electrically connect the data line DL and the first electrode of the first transistor T1.

The third transistor T3 is connected between the second electrode of the first transistor T1 and the control electrode. The control electrode of the third transistor T3 is connected to the i-th scan line SLi. When the i-th scan signal Si is provided to the i-th scan line SLi, the third transistor T3 is turned on to electrically connect the second electrode of the first transistor T1 and the control electrode. Accordingly, when the third transistor T3 is turned on, the first transistor T1 is connected in the form of a diode.

The fourth transistor T4 is connected between the node ND and an initialization power generation unit (not shown). In addition, the control electrode of the fourth transistor T4 is connected to the (i−1)-th scan line SLi−1. When the (i−1)-th scan signal Si−1 is provided to the (i−1)-th scan line SLi−1, the fourth transistor T4 is turned on to provide an initialization voltage Vint to the node ND.

The fifth transistor T5 is connected between a power line PL and the first electrode of the first transistor T1. The control electrode of the fifth transistor T5 is connected to the i-th light-emission control line ECLi.

The sixth transistor T6 is connected between the second electrode of the first transistor T1 and the anode electrode of the light-emitting diode LD. In addition, the control electrode of the sixth transistor T6 is connected to the i-th light-emission control line ECLi.

The seventh transistor T7 is connected between the initialization power generation unit (not shown) and the anode electrode of the light-emitting diode LD. In addition, the control electrode of the seventh transistor T7 is connected to the (i+1)-th scan line SLi+1. When the (i+1)-th scan signal Si+1 is provided to the (i+1)-th scan line SLi+1, such seventh transistor T7 is turned on to provide the initialization voltage Vint to the anode electrode of the light-emitting diode LD.

The seventh transistor T7 may improve the black expression capability of the pixel PX. Specifically, when the seventh transistor T7 is turned on, a parasitic capacitor (not shown) of the light-emitting diode LD is discharged. Due to this discharge of parasitic capacitance, when the black luminance is implemented, the light-emitting diode LD does not emit light due to the leakage current from the first transistor T1. Accordingly, the black expression capability may be improved.

Additionally, in FIG. 4, the control electrode of the seventh transistor T7 is shown to be connected to the (i+1)-th scan line SLi+1, but the present disclosure is not limited to this configuration. In another embodiment of the present disclosure, the control electrode of the seventh transistor T7 may be connected to the i-th scan line SLi or the (i−1)-th scan line SLi−1.

Illustration of FIG. 4 is based on PMOS, but the present disclosure is not limited to this configuration. In another embodiment of the present disclosure, the pixel PX may be composed of NMOS. In another embodiment of the present disclosure, the pixel PX may be composed of a combination of NMOS and PMOS.

The capacitor CP is interposed between the power line PL and the node ND. The capacitor CP is configured to store a voltage corresponding to the data signal. When the fifth transistor T5 and the sixth transistor T6 are turned on, the amount of current flowing through the first transistor T1 may be determined according to the voltage stored in the capacitor CP.

In the present disclosure, the structure of the pixel PX is not limited to what is illustrated in FIG. 4. In another embodiment of the present disclosure, the pixel PX may be implemented in any one of various forms configured for the light-emitting diode LD to emit light.

Referring to FIG. 5, the light emission control signal Ei may have a high level E-HIGH or a low level E-LOW. Each of the scan signals SLi−1, SLi, and SLi+1 may have a high level S-HIGH or a low level S-LOW.

When the light emission control signal Ei has a high level E-HIGH, the fifth transistor T5 and the sixth transistor T6 are turned off. When the fifth transistor T5 is turned off, the power line PL and the first electrode of the first transistor T1 are electrically cut off. When the sixth transistor T6 is turned off, the second electrode of the first transistor T1 and the anode electrode of the light-emitting diode LD are electrically cut off. Accordingly, the light-emitting diode LD does not emit light while the light emission control signal Ei having a high level E-HIGH is provided to the i-th light emission control line ECLi.

Thereafter, when the (i−1)-th scan signal Si−1 provided to the (i−1)-th scan line SLi−1 has a low level S-LOW, the fourth transistor T4 is turned on. When the fourth transistor T4 is turned on, the initialization voltage Vint is provided to the node ND.

When the i-th scan signal Si provided to the i-th scan line SLi has a low level S-LOW, the second transistor T2 and the third transistor T3 are turned on.

When the second transistor T2 is turned on, a data signal is provided to the first electrode of the first transistor T1. Here, since the node ND is initialized to the initialization voltage Vint, the first transistor T1 is turned on. When the first transistor T1 is turned on, a voltage corresponding to the data signal is provided to the node ND. Here, the capacitor CP stores a voltage corresponding to the data signal.

When the (i+1)-th scan signal Si+1 provided to the (i+1)-th scan line SLi+1 has a low level S-LOW, the seventh transistor T7 is turned on.

When the seventh transistor T7 is turned on, the initialization voltage Vint is provided to the anode electrode of the light-emitting diode LD, thereby discharging the parasitic capacitor of the light-emitting diode LD.

When the light emission control signal Ei provided to the light emission control line ECLi has a low level E-LOW, the fifth transistor T5 and the sixth transistor T6 are turned on. When the fifth transistor T5 is turned on, the first power ELVDD is provided to the first electrode of the first transistor T1. When the sixth transistor T6 is turned on, the second electrode of the first transistor T1 and the anode electrode of the light-emitting diode LD are electrically connected. Then, the light-emitting diode LD generates light of a predetermined luminance in response to the amount of supplied current.

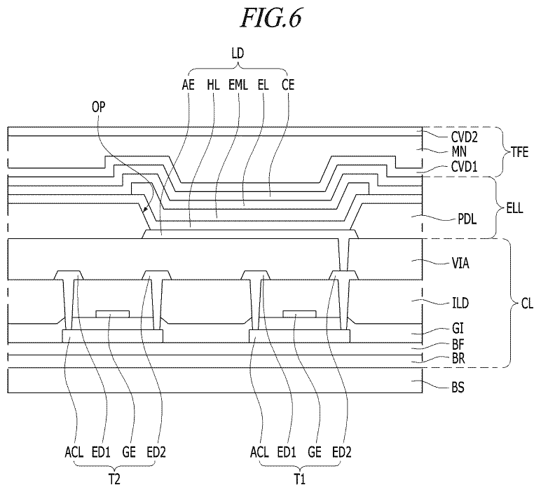

FIG. 6 is a cross-sectional view illustrating a portion of a pixel PX (see FIG. 4) according to an embodiment of the present disclosure. An example of the first transistor T1 and the second transistor T2 is illustrated in FIG. 6, but the structures of the first transistor T1 and the second transistor T2 are not limited to what is illustrated in FIG. 6. In FIG. 6, the second electrode ED2 of the first transistor T1 is shown to make direct contact with the anode electrode AE of the pixel PX. However, this is partly due to the position of the cross-sectional shape that is shown, and in fact, as shown in FIG. 4, the first transistor T1 may be connected to the anode electrode AE of the pixel PX through the sixth transistor T6. It should be understood that the present disclosure is not limited to the configuration that is depicted, and in an embodiment of the present disclosure, the second electrode ED2 of the first transistor T1 may make direct contact with the anode electrode AE of the pixel PX.

The display panel DP (see FIG. 3) may include a circuit layer CL, a light-emitting layer ELL, and an encapsulation layer TFE.

The circuit layer CL may include a barrier layer BR, a buffer layer BF, gate insulating layers GI, an interlayer insulating layer ILD, a circuit insulating layer VIA, and transistors T1 and T2.

The light-emitting layer ELL may be disposed on the circuit layer CL. The light-emitting layer ELL may include a light-emitting diode LD and a pixel defining film PDL.

The encapsulation layer TFE may be configured to seal off the light-emitting layer ELL to protect the light-emitting layer ELL from external oxygen or moisture.

The encapsulation layer TFE may include a first encapsulation inorganic layer CVD1, an encapsulation organic layer MN, and a second encapsulation inorganic layer CVD2. In FIG. 6, the encapsulation layer TFE is illustrated, as an example, to include two encapsulation inorganic layers and one encapsulation organic layer, but the present disclosure is not limited to this example. For example, the encapsulation layer TFE may include three encapsulation inorganic layers and two encapsulation organic layers, and in this case, the encapsulation inorganic layers and the encapsulation organic layers may be alternately laminated.

Functional layers BR and BF may be disposed on one side of a base layer BS. The functional layer BR and BF may include a barrier layer BR and a buffer layer BF.

The functional layers BR and BF are configured to prevent impurities existing in the bottom layer from flowing into the pixel PX during the manufacturing process. In particular, diffusion of impurities into active parts ACL of the transistors T1 and T2 composing the pixel PX is prevented.

The active parts ACL composing each of the transistors T1 and T2 are disposed on the buffer layer BF. Each of the active parts ACL may include polysilicon or amorphous silicon. Other active parts ACL may include a metal oxide semiconductor.

The active parts ACL may include a channel area serving as a passage through which electrons or holes may move, and a first ion-doped area and a second ion-doped area disposed with the channel area therebetween.

A gate insulting layer GI covering the active parts ACL is disposed on the buffer layer BF. The gate insulating layer GI includes an organic and/or an inorganic film. The gate insulating layer GI may include a plurality of inorganic thin films. The plurality of inorganic thin films may include a silicon nitride layer and a silicon oxide layer.

Control electrodes GE in each of the transistors T1 and T2 are disposed on the gate insulating layer GI. At least a portion of the scan lines SL (see FIG. 4) and the light emission control lines ECL (see FIG. 4) may be disposed on the gate insulating layer GI.

An interlayer insulating layer ILD covering the control electrodes GE is disposed on the gate insulating layer GI. The interlayer insulating layer ILD includes an organic and/or an inorganic layer. The interlayer insulating layer ILD may include a plurality of inorganic thin films or organic thin films. The plurality of inorganic thin films may include a silicon nitride layer and a silicon oxide layer.

At least a portion of the data line DL (see FIG. 4) and the power line PL (see FIG. 4) may be disposed on the interlayer insulating layer ILD. The first electrodes ED1 and the second electrodes ED2 of each of the transistors T1 and T2 may be disposed on the interlayer insulating layer ILD.

The first electrodes ED1 and the second electrodes ED2 may be connected to the corresponding active parts ACL through contact holes penetrating the gate insulating layer GI and the interlayer insulating layer ILD, respectively.

A circuit insulating layer VIA covering the first electrodes ED1 and the second electrodes ED2 is disposed on the interlayer insulating layer ILD. The circuit insulating layer VIA includes an organic layer and/or an inorganic layer. The circuit insulating layer VIA may provide a flat surface. The circuit insulating layer VIA may be interposed between the anode electrode AE and the transistors T1 and T2. A pixel defining film PDL and a light-emitting diode LD are disposed on the circuit insulating layer VIA.

The light-emitting diode LD may include an anode electrode AE, a hole control layer HL, a light-emitting diode layer EML, an electron control layer EL, and a cathode electrode CE.

An anode electrode AE may be connected to the second electrode ED2 through contact holes penetrating the circuit insulating layer VIA.

An opening part OP defined in the pixel defining film may be configured to expose the anode electrode AE.

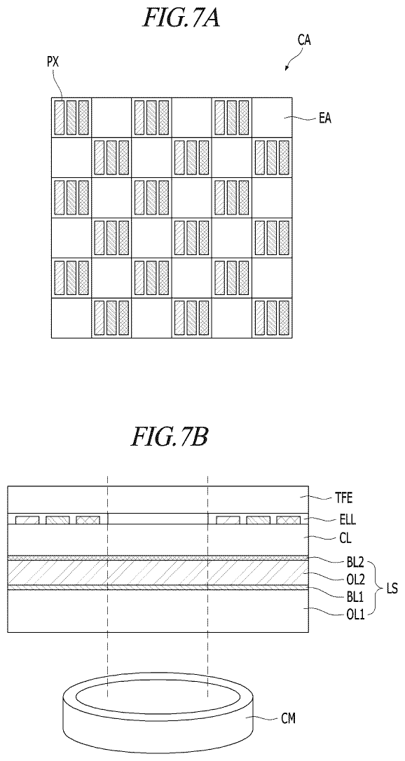

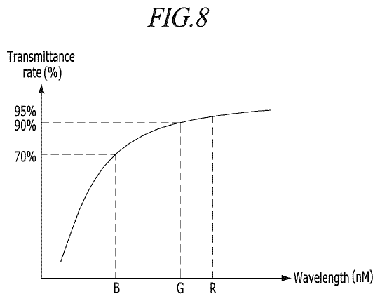

FIG. 7A is a magnified view of a portion of the pixels PX disposed in the camera area CA of FIG. 1. Each of the plurality of pixels may emit one of red light, green light, and blue light.

The plurality of pixels PX may be disposed in blocks. Otherwise, the plurality of pixels PX may be disposed apart from each other. According to an embodiment of the present disclosure, the camera area CA may include a plurality of empty areas EA where pixels PX are not disposed.

The plurality of pixels PX and the plurality of empty areas EA may be arranged alternately to form a checkerboard pattern. However, the embodiment is not limited to this arrangement, and the plurality of pixels PX and the plurality of empty areas EA may be arranged randomly or according to a different pattern. In addition, the number of the plurality of pixels PX may not be the same as the number of the plurality of empty areas EA.

Pixel per inch PPI of the camera area CA may be the half of pixel per inch PPI of the display area other than the camera area CA. However, the embodiment is not limited to this configuration, and the PPI may be a different value depending on a pixel PX size.

FIG. 7B is a cross-sectional view of the camera area shown in FIG. 1. FIG. 8 is a graph illustrating transmissivity per wavelength of red light, green light and blue light. Specifically, FIG. 8 illustrates transmissivity as a function of wavelength of light traveling through a set of layers shown in FIG. 7B.

In an embodiment of the present disclosure, the set of layers LS may be disposed below the circuit layer CL. The camera module CM may be disposed below the set of layers LS.

The set of layers LS may include a first organic layer OL1, a first barrier layer BL1, a second organic layer OL2, and a second barrier layer BL2. Each of the first organic layer OL1 and the second organic layer OL2 may include an organic material (e.g. polyimide), and each of the first barrier layer BL1 and the second barrier layer BL2 may include an inorganic material. The first organic layer OL1 may be disposed on the base substrate (not shown). The first barrier layer BL1 may be disposed on the first organic layer OL1. The second organic layer OL2 may be disposed on the first barrier layer BL1. The second barrier layer BL2 may be disposed on the second organic layer OL2.

In an embodiment of the present disclosure, the first organic layer OL1 and the second organic layer OL2 may be opaque. Here, each of the first organic layer OL1 and the second organic layer OL2 may include a material of Formula (I):

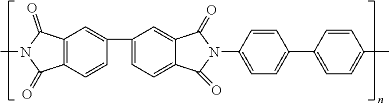

When the first organic layer OL1 and the second organic layer OL2 are opaque, the light transmissivity of the set of layers LS for blue light may be 65% and the light transmissivity of the set of layers LS for green light may be 90%. In this case, the photograph may look yellow due to a fairly large difference between light transmissivities of blue light and green light. In addition, each of the first organic layer OL1 and the second organic layer OL2 including Formula (I) is essentially yellow. Accordingly, implementation of Under Panel Camera UPC in combination with the first organic layer OL1 and the second organic layer OL2, which are opaque, decreases light transmissivity to the point that a lot of corrections through a software program may be needed after taking the photograph. Where percentages are mentioned, the upper limit is understood to be 100% unless another value is explicitly provided.

Nonetheless, as an adhesiveness between the second organic layer OL2 and the first barrier layer BL1 is excellent, the second organic layer OL2 and the first barrier layer BL1 do not peel off from each other during the process of cell-cut. This secure adhesion forms a barrier that external oxygen and moisture cannot penetrate.

In an embodiment of the present disclosure, the first organic layer OL1 and the second organic layer OL2 may be transparent, thereby avoiding the decreased light transmissivity and the need for a lot of corrections after taking the photograph. Here, the first organic layer OL1 and the second organic layer OL2 may include a material of Formula (II):

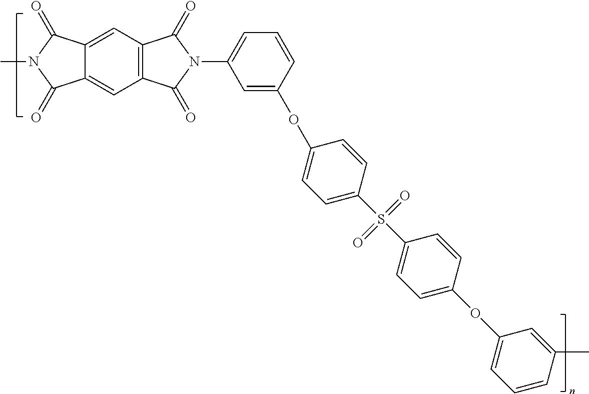

The transparent polyimide of Formula (II) may have an asymmetric structure or a twisted structure. Lamination of such structure may increase distances between transparent polyimides. Accordingly, as transmitted light may be dispersed through spaces formed by twisted structures of polyimides, the organic layer may be transparent.

As described above, when the first organic layer OL1 and the second organic layer OL2 are transparent, the light transmissivity of the set of layers LS for blue light may be 70% or more, and the light transmissivity of the set of layers LS for green light may be 90% or more. (See FIG. 8). As such, since difference between light transmissivities of blue light and green light is reduced, the likelihood and extent of the resulting photograph turning yellow may be reduced in a hardware-wise manner. As the first organic layer OL1 and the second organic layer OL2 are transparent, less post-correction is required and light transmissivity is increased to implement clearer camera resolution when a photograph or video is taken.

Hereinafter, camera module operations of FIGS. 7A, 7B and 8 are described to in the context of taking a photograph or a video. However, the present disclosure is not limited to the illustrations in FIGS. 7A, 7B and 8, and it may be applicable to situations, such as user biometrics, for unlocking a display device.

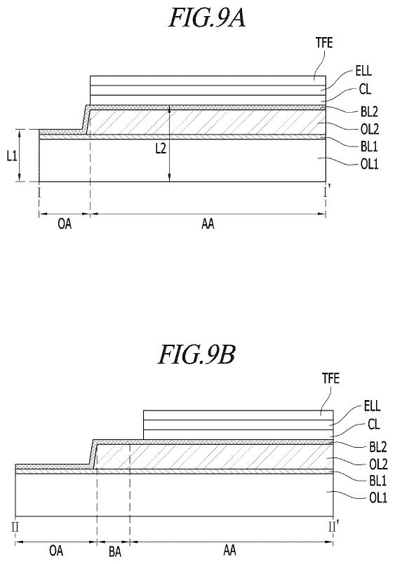

FIG. 9A is an exemplary illustration of a portion of a cross-section taken along the line I-I′ of FIG. 1. FIG. 9A illustrates a cross-sectional shape taken along the line I-I′ on the left of the display device DD of FIG. 1, but the present disclosure is not limited to what is illustrated in FIG. 9A. An exemplary illustration of a portion of a cross-section taken from the right side or the top side of the display device DD may be substantially the same as what is illustrated in FIG. 9A.

Referring to FIG. 9A, the first organic layer OL1, the first barrier layer BL1, the second organic layer OL2 and the second barrier layer BL2 may be correspond to the base layer BS illustrated in FIG. 6. Among the above, the second barrier layer BL2 may be omitted or correspond to the barrier layer BR illustrated in FIG. 6.

The active area AA may be defined as an area where a circuit layer CL, a light-emitting layer ELL, and an encapsulation layer TFE are disposed. In addition, an outermost area OA may be defined as an outer area of the display device DD that does not belong to the active area AA. The first barrier layer BL1 and the second barrier layer BL2 may make contact within the outermost area OA.

According to an embodiment of the present disclosure, a portion of the second organic layer OL2 may be patterned, and the second barrier layer BL2 may be disposed on one side thereof. The second barrier layer BL2 may cover the surface or outer portion of the second organic layer OL2, including any sidewall. During the process, the first barrier layer BL1 including an inorganic material and the second barrier layer BL2 including an inorganic material may make contact. As an inorganic material strongly binds with another inorganic material, peeling may not occur. Accordingly, it will be difficult for any oxygen and moisture to penetrate between the first barrier layer BL1 and the second barrier layer BL2. Hence, oxygen and moisture may not penetrate between the second organic layer OL2 and the first barrier BL1 either.

In addition, in FIG. 9A, only the second organic layer OL2 is patterned so that a thickness of the first organic layer OL1 and a thickness of the first barrier layer BL1 may not change within the active area AA and the outermost area OA.

However, as described above, in FIG. 9A, the second barrier layer BL2 covers the surface or an outer portion of the patterned second organic layer OL2. In the outermost area OA, the second barrier layer BL2 may be spaced apart from the most bottom portion of the first organic layer OL1 by a first spacing distance L1. In the active area AA, the second barrier layer BL2 may be spaced apart from the most bottom portion of the first organic layer OL1 by a second spacing distance L2, which may be greater than the first spacing distance L1.

FIG. 9B is an exemplary illustration of a portion of a cross-section taken along the line II-II′ of FIG. 1. FIG. 9B exemplarily illustrates a portion of a cross-section of the bottom of the display device DD of FIG. 1.

In FIG. 9B, the active area AA and the outermost area OA may be defined as in FIG. 9A. However, in FIG. 9B, which illustrates a cross-section of the bottom of the display device DD, a bending area BA may be defined between the active area AA and the outermost area OA. This bending area BA is also illustrated in FIG. 3.

The outermost area of FIG. 9A does not overlap with the active area AA. In the embodiment of of FIG. 9B, which includes the bending area BA, the outermost area OA may overlap with the active area AA as the bending area is bent. Accordingly, the second barrier layer BL2 disposed in the active area AA may overlap with the second barrier layer BL2 disposed in the outermost area OA.

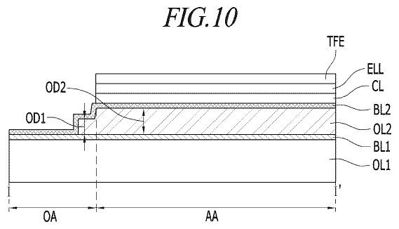

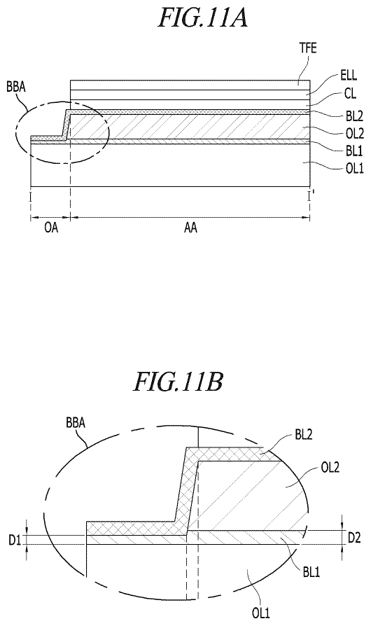

FIG. 10 is an exemplary illustration of a portion of a cross-section taken along the line I-I′ of FIG. 1 in accordance with another embodiment of the present disclosure. In FIG. 10, the active area AA and the outermost area OA may be defined similarly to in FIG. 9A. Description of the configuration is omitted as it is the same as the above description. In addition, in FIG. 10, only a portion of the second organic layer OL2 is patterned so that a thickness of the first organic layer OL1 and a thickness of the first barrier layer BL1 may not change within the active area AA and the outermost area OA. In FIG. 10, there is a step formed in the second organic layer OL2 such that the second organic layer OL2 has a first organic layer thickness OD1 in the outermost area OA and a second organic layer thickness OD2 in the active area AA. The first organic layer thickness OD1 may be smaller than the second organic layer thickness OD2.

According to an embodiment of the present disclosure, a portion of the second organic layer OL2 is patterned, and the second barrier layer BL2 may be disposed on one side thereof. Hereinafter, the subsequent process may be the same as what is described above in FIG. 9A, and thus may be omitted.

FIG. 11A is an exemplary illustration of a portion of a cross-section taken along the I-I′ of FIG. 1 in accordance with yet another embodiment of the present disclosure. FIG. 11B is a magnified view of a portion marked “BBA” in FIG. 11A.

According to an embodiment of the present disclosure, when the second organic layer OL2 is patterned, some of the first barrier layer BL1 may also be patterned. Then, the second barrier layer BL2 may be disposed on one side thereof. As shown in FIG. 11B, the first barrier layer BL1 has a first thickness D1 in the outermost area OA and a second thickness D2 in the active area AA. The first thickness D1 may be smaller than the second thickness D2.

In comparison to the previous descriptions of other embodiments, the second barrier layer BL2 may cover an outer portion, including a sidewall, of the second organic layer OL2 in the embodiment. Therefore, the effect of sealing between the second organic layer OL2 and the first barrier layer BL1 by the second barrier layer BL2 may be enhanced.

Accordingly, external oxygen and moisture may not travel between the first barrier layer BL1 and the second barrier layer BL2, and therefore external oxygen and moisture may not penetrate between the second organic layer OL2 and the first barrier layer BL1 as well.

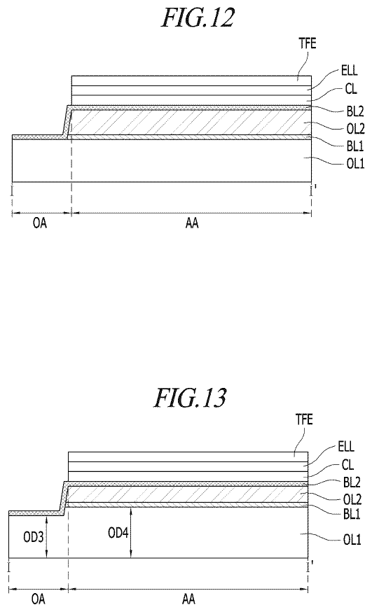

FIG. 12 is an exemplary illustration of a portion of a cross-section taken along the I-I′ of FIG. 1 in accordance with still another embodiment of the present disclosure.

According to an embodiment of the present disclosure, when the second organic layer OL2 is patterned, the first barrier layer BL1 may also be patterned. Then, the second barrier layer BL2 may be disposed on one side thereof. Accordingly, the second barrier layer BL2 may make contact with the first organic layer OL1 within the outermost area OA.

In comparison to the previous descriptions of other embodiments, the second barrier layer BL2 may further cover an outer portion of the second organic layer OL2 in the embodiment. Therefore, the effect of sealing between the second organic layer OL2 and the first barrier layer BL1 by the second barrier layer BL2 may be enhanced.

Accordingly, external oxygen and moisture may not travel across the first barrier layer BL1 and the second barrier layer BL2, and therefore external oxygen and moisture may not penetrate between the second organic layer OL2 and the first barrier layer BL1 as well.

FIG. 13 is an exemplary illustration of a portion of a cross-section taken along the line I-I′ of FIG. 1 in accordance with still yet another embodiment of the present disclosure.

According to an embodiment of the present disclosure, when the second organic layer OL2 is patterned, some the first organic layer OL1 may also be patterned. Then, the second barrier layer BL2 may be laminated on one side thereof, including a sidewall. Accordingly, the second barrier layer BL2 may make contact with the first organic layer OL1 within the outermost area OA.

Referring to FIG. 13, the first organic layer OL1 has a third thickness OD3 in the outermost area OA and a fourth thickness OD4 in the active area AA. The third thickness OD3 may be smaller than the fourth thickness OD4.

In comparison to the previous descriptions of other embodiments, the second barrier layer BL2 may further cover an outer portion of the second organic layer OL2 in the embodiment. Therefore, the effect of sealing between the second organic layer OL2 and the first barrier layer BL1 by the second barrier layer BL2 may be enhanced.

Accordingly, external oxygen and moisture may not travel across the first barrier layer BL1 and the second barrier layer BL2, and therefore external oxygen and moisture may not penetrate between the second organic layer OL2 and the first barrier layer BL1 as well.

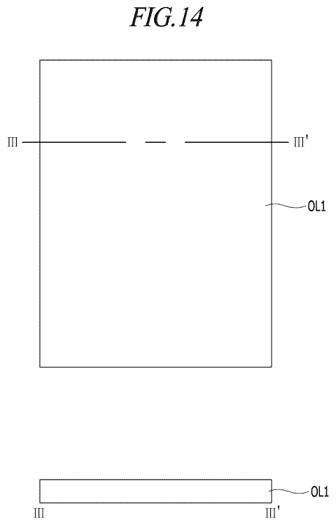

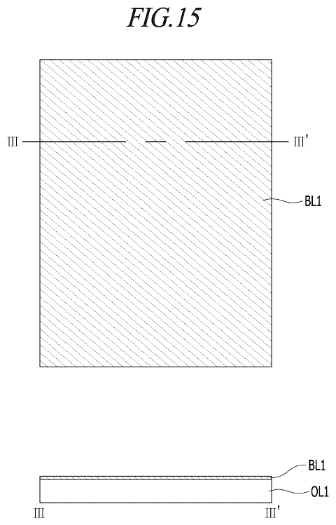

FIGS. 14 through 20D are exemplary illustrations of processes involved in a method of preparing a display panel according to an embodiment of the present disclosure. In FIGS. 14 through 20D, a base substrate including glass may be disposed at the bottom, but it is not shown for convenience. Hereinafter, to focus on describing the technical idea of the present disclosure, the description of base substrate at the bottom is omitted.

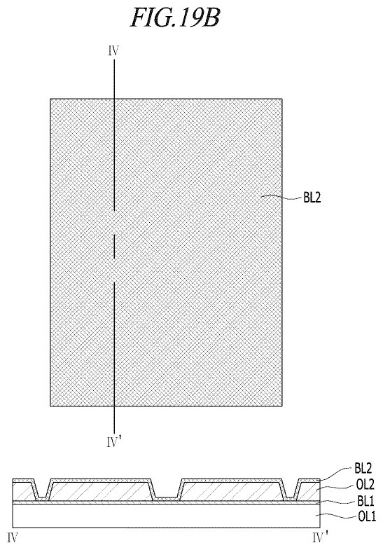

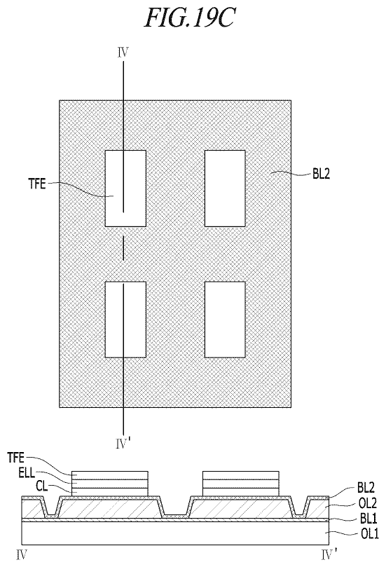

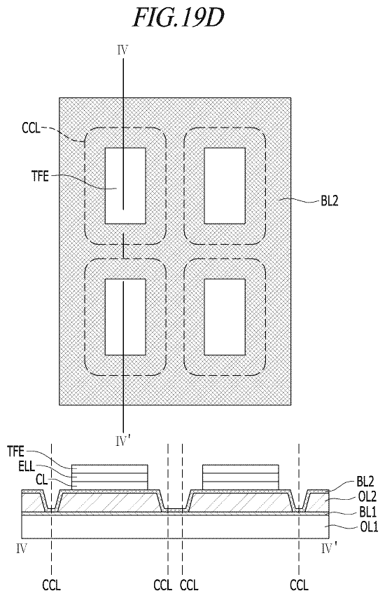

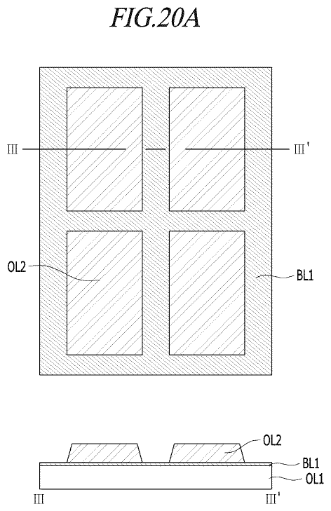

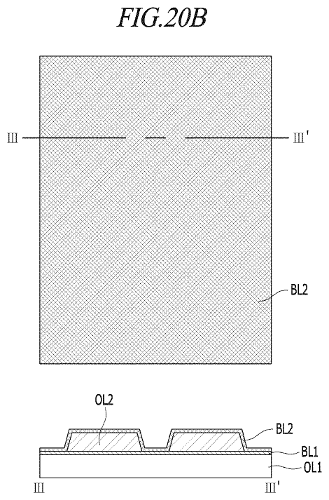

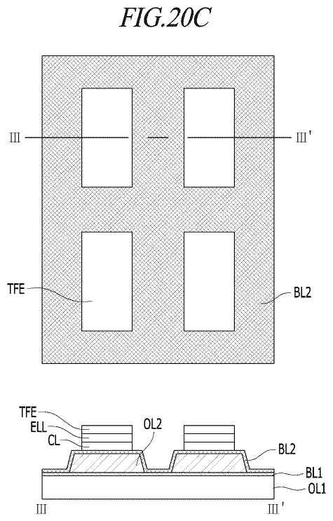

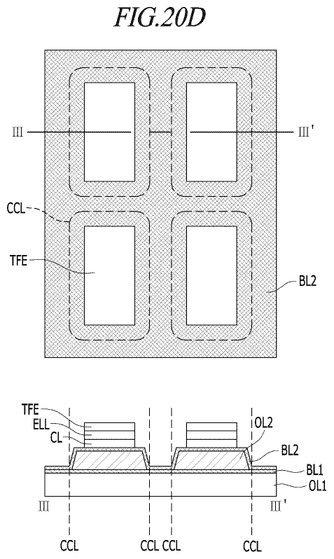

Four processes are exemplarily illustrated as embodiments of the present disclosure. FIGS. 14 through 16 are plan views and cross-sectional views corresponding to each process that is common in the four embodiments. FIGS. 17A through 17D are plane views and cross-sectional views of a first embodiment among the four processes following the processes illustrated in FIGS. 14 through 16. FIGS. 18A through 18D are plan views and cross-sectional views of a second embodiment among the four processes following the processes illustrated in FIGS. 14 through 16. FIGS. 19A through 19D are plan views and cross-sectional views of a third embodiment among the four processes following the processes illustrated in FIGS. 14 through 20 16. FIGS. 20A through 20D are plan views and cross-sectional views of a fourth embodiment among the four processes following the processes illustrated in FIGS. 14 through 16.

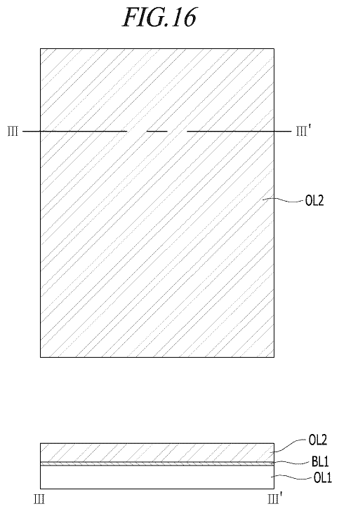

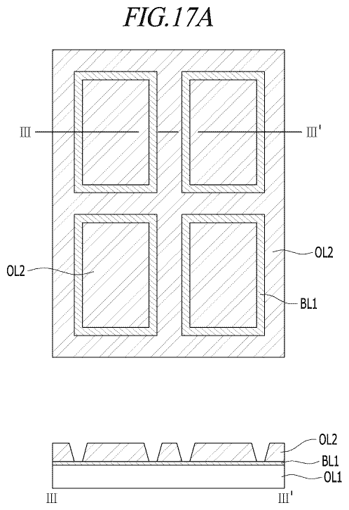

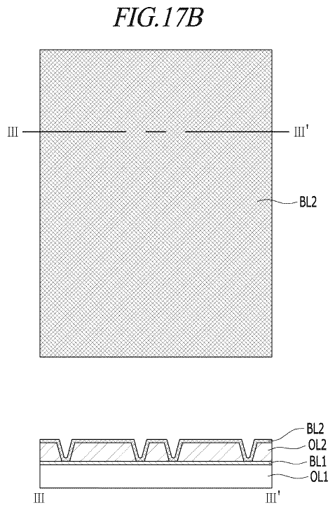

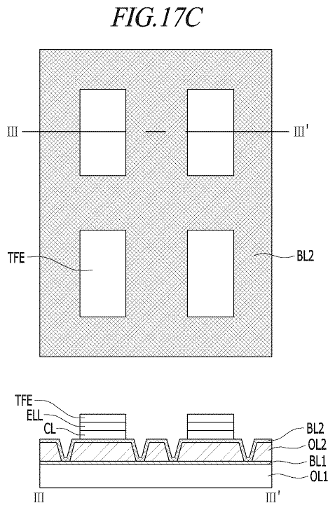

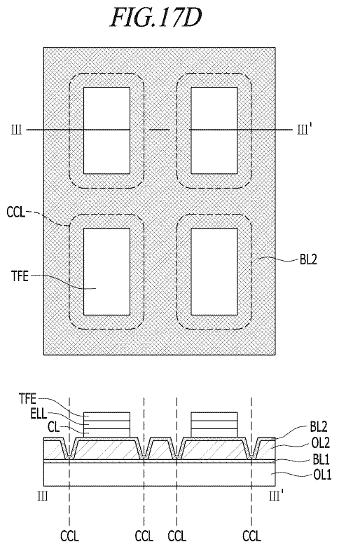

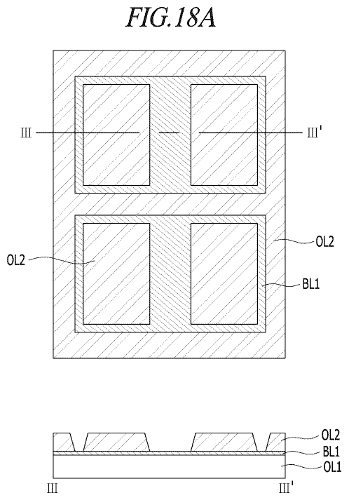

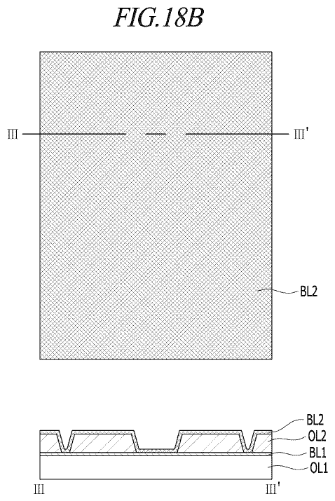

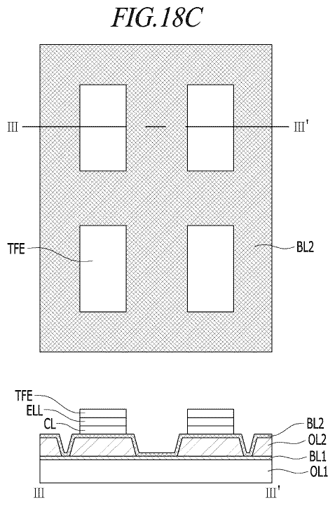

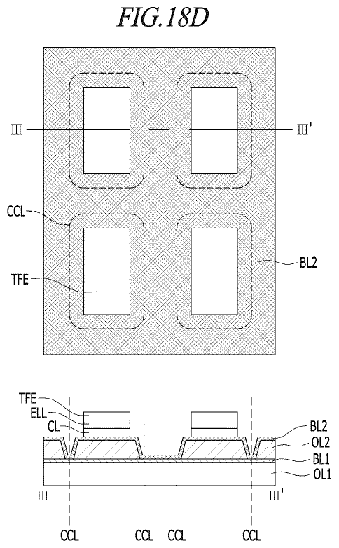

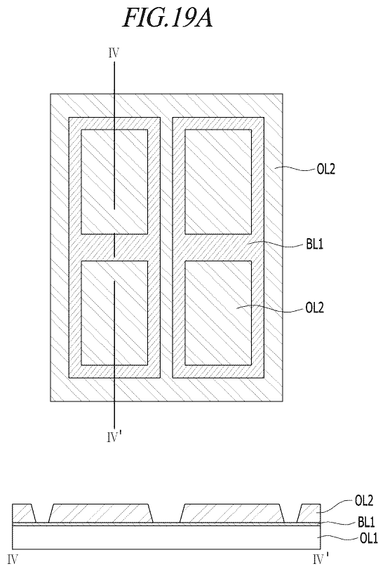

Referring to FIG. 14, a first organic layer OL1 may be disposed on a base substate (not shown). Referring to FIG. 15, a first barrier layer BL1 may be disposed on the first organic layer OL1. Referring to FIG. 16, a second organic layer OL2 may be disposed on the first barrier layer BL1. The processes illustrated in FIGS. 14 through 16 are common in the four embodiments, subsequent processes of which are illustrated in FIGS. 17A through 17D, FIGS. 18A through 18D, FIGS. 19A through 19D, and FIGS. 20A through 20D.

FIGS. 17A through 17D are plan views and cross-sectional views of an embodiment of the present disclosure.

Referring to FIG. 17A, the second organic layer OL2 may have a partially etched shape after the patterning process.

Referring to FIG. 17B, a second barrier layer BL2 may be disposed on the second organic layer OL2. Referring to FIG. 17C, a circuit layer CL may be disposed on the second barrier layer BL2. A light-emitting layer ELL may be disposed on the circuit layer CL. An encapsulation layer TFE may be disposed on the light-emitting layer ELL.

Referring to FIG. 17D, a cell-cut process may be performed along a cutting line CCL in the area where the first barrier layer BL1 makes contact with the second barrier layer BL2.

FIGS. 17A through 17D illustrate an embodiment where the second organic layer OL2 has the minimum patterned area. There may be a challenge in patterning only the minimum area of the second organic layer OL2 surrounding the active area AA, which may involve a complex process. However, minimizing the patterned area may be economically advantageous. The cell-cut process may be performed after removing the base substrate (not shown) that is under the first organic layer OL1. The cell-cut line for the cell-cut process is uniformly illustrated in the figures. However, the present disclosure is not limited to what is illustrated in the figures, and the width of the cell-cut line for performing the process may be changed.

FIGS. 18A through 18D are plan views and cross-sectional views according to an embodiment of the present disclosure. FIGS. 18A through 18D, illustrate an embodiment of patterning the second organic layer OL2 by grouping horizontally adjacent cells.

In comparison to the embodiment of FIGS. 17A through 17D, the embodiment of FIGS. 18A through 18D may have a higher cost. However, it may be relatively advantageous in that the patterning process is less complex. Descriptions of technical features including the cell-cut process are substantially the same as the descriptions about FIGS. 17A through 17D, and therefore omitted.

FIGS. 19A through 19D are plan views and cross-sectional views of an embodiment of the present disclosure. FIGS. 19A through 19D illustrate an embodiment of patterning the second organic layer OL2 by grouping vertically adjacent cells. In comparison to the embodiment of FIGS. 17A through 17D, the embodiment of FIGS. 19A through 19D may have less complex patterning process. Descriptions of technical features including the cell-cut process are substantially the same as the descriptions about FIGS. 17A through 17D, and therefore omitted.

FIGS. 20A through 20D are plan views and cross-sectional views of an embodiment of the present disclosure. FIGS. 20A through 20D illustrate an embodiment where the second organic layer OL2 has the maximum patterned area. The process of patterning the maximum area of the second organic layer OL2 other than the active area AA may be costly. Nonetheless, in comparison to other embodiments described above, the patterning process may be less complex. Descriptions of technical features including the cell-cut process are substantially the same as the descriptions about FIGS. 17A through 17D, and therefore omitted.

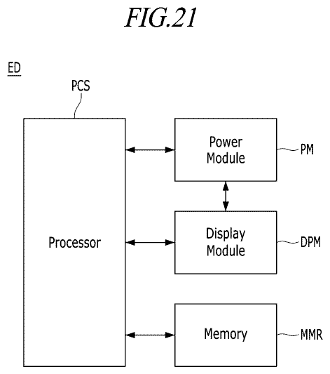

Referring to FIG. 21, the electronic device ED according to an embodiment may include a display module DPM, a processor PCS, a memory MMR, and a power module PM.

The processor PCS may include at least one of a central processing unit CPU, an application processor AP, a graphic processing unit GPU, a communication processor CP, an image signal processor ISP, and a controller.

The memory MMR may be configured to store data information for operation of the processor PCS or the display module DPM. In the case that the processor PCS operates an application stored in the memory MMR, the display module DPM may be configured to receive an image data signal and/or an input control signal and process the received signal to provide an output of image information through a display screen.

A power module PM may include a power supply module, such as a power adapter or a battery device, and a power conversion module, which converts power supplied by the power supply module to generate power required for operation of an electronic device ED.

At least one of the elements of the above electronic device ED may be included in the display device according to the above embodiments. In addition, some of individual modules functionally included in a single module may be included in the display device, and the other may be provided separately from the display device. For example, a display module may be included in the display device, and the processor PCS, the memory MMR, and the power module PM may be provided in a form of another device within the electronic device ED other than the display device.

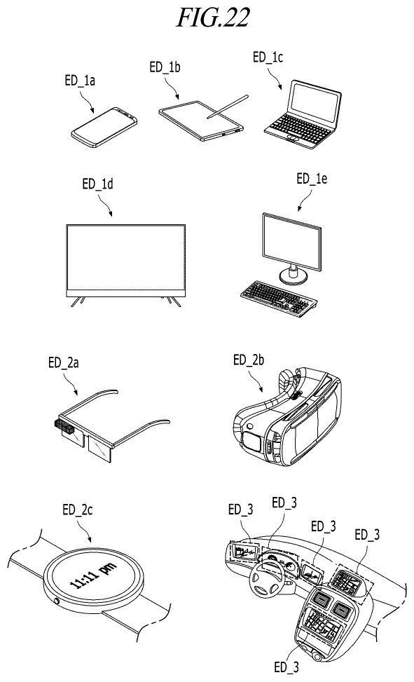

Referring to FIG. 22, various electronic devices having display devices according to embodiments may include not only an image display electronic device, such as a smart phone ED-1a, a tablet PC ED-1b, a laptop ED-1c, a TV ED-1d, and a desk monitor ED-1e, but also a wearable electronic device including a display module, such as smart glass ED-2a, a head mounted display ED-2b, and a smart watch ED-2c, and a vehicle electronic device ED-3 including a display module, such as a CID (Center Information Display) and a room mirror display disposed on an instrument panel, center fascia, and a dashboard of an automobile.

While certain embodiments of the present disclosure have been described above, anyone of ordinarily skill in the art to which the present disclosure pertains shall appreciate that there may be a variety of modifications and permutations of the present disclosure without departing from the technical ideas and scopes of the present disclosure that are defined in the appended claims. Moreover, it shall be appreciated that the disclosed embodiments are not intended to restrict the present disclosure thereto and that every technical idea within the appended claims and their equivalents is interpreted to be included in the scope of the present disclosure.

What is claimed is:

1. A display device comprising:
a first organic layer comprising an organic material;
a first barrier layer disposed on the first organic layer and comprising an inorganic material;
a second organic layer disposed on the first barrier layer and comprising an organic material;
a second barrier layer disposed on the second organic layer and comprising an inorganic material, one portion of the second barrier layer making contact with one portion of the first barrier layer;
a circuit layer disposed on the second barrier layer and comprising a plurality of transistors;
a light-emitting layer disposed on the circuit layer and comprising a plurality of light-emitting diodes; and
an encapsulation layer disposed on the light-emitting layer.

2. The display device of claim 1, wherein the circuit layer, the light-emitting layer, and the encapsulation layer do not overlap with the one portion of the first barrier layer.

3. The display device of claim 2, wherein each of the first organic layer and the second organic layer is configured to transmit at least some of incident light.

4. The display device of claim 3, wherein at least 70% of blue light having a wavelength of 450 nm that is incident on the second barrier layer is transmitted through the first organic layer.

5. The display device of claim 4, further comprising a camera module disposed under the first organic layer and having one portion thereof overlapping with at least one of the plurality of light-emitting diodes,
wherein the camera module is configured to detect light transmitted through at least one of the first organic layer and the second organic layer.

6. The display device of claim 2, wherein a thickness of the one portion of the first barrier layer is smaller than a thickness of another portion of the first barrier layer.

7. The display device of claim 2, wherein the one portion of the second barrier layer make contact with the one portion of the first organic layer.

8. The display device of claim 7, wherein a thickness of the one portion of the first organic layer is smaller than a thickness of another portion of the first organic layer.

9. The display device of claim 1, wherein a portion of the second barrier layer adjacent to the one portion is bent.

10. The display device of claim 9, wherein the one portion of the second barrier layer overlaps with another portion of the second barrier layer.

11. A display device comprising:
a display panel defined with a display area configured to display an image and a non-display area surrounding the display area, the display panel comprising:
a first organic layer comprising an organic material;
a first barrier layer disposed on the first organic layer and comprising an inorganic material;
a second organic layer disposed on the first barrier layer and comprising an organic material;
a second barrier layer covering the second organic layer and comprising an inorganic material, a portion of the second barrier layer corresponding to the non-display area making contact with the first barrier layer;
a plurality of transistors disposed on the second barrier layer; and
a plurality of light-emitting diodes electrically connected with the plurality of transistors.

12. The display device of claim 11, wherein an area of the first organic layer is greater than an area of the second organic layer.

13. The display device of claim 12, wherein each of the first organic layer and the second organic layer is configured to transmit at least some of incident light.

14. The display device of claim 13, wherein each of the first organic layer and the second organic layer comprises a material of Formula 1:

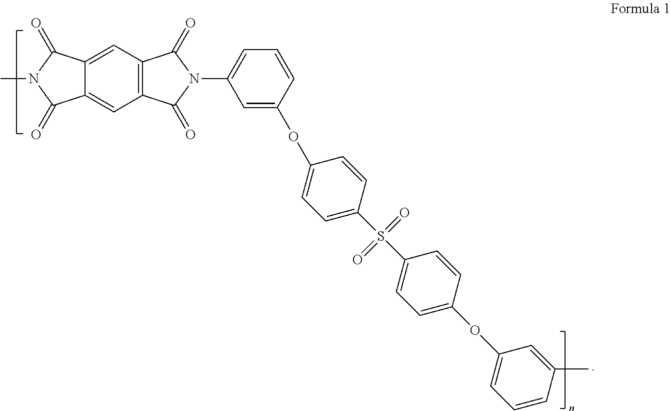

15. The display device of claim 13, further comprising a camera module disposed under the first organic layer,
wherein the camera module is configured to detect light that has passed through at least one of the first organic layer and the second organic layer.

16. The display device of claim 12, wherein a thickness of a portion of the first barrier layer making contact with the second barrier layer is smaller than a thickness of another portion of the first barrier layer.

17. The display device of claim 12, wherein the portion of the second barrier layer corresponding to the non-display area makes contact with one portion of the first organic layer.

18. The display device of claim 12, wherein a thickness of a portion of the first organic layer corresponding to the non-display area is smaller than a thickness of a portion of the first organic layer corresponding to the display area.

19. The display device of claim 12, wherein a portion of the second barrier layer adjacent to the portion of the second barrier layer making contact with the first barrier layer is bent, and the portion of the second barrier layer making contact with the first barrier layer overlaps with another portion of the second barrier layer.

20. An electronic device comprising:
a first organic layer comprising an organic material;
a first barrier layer disposed on the first organic layer and comprising an inorganic material;
a second organic layer disposed on the first barrier layer and comprising an organic material;
a second barrier layer disposed on the second organic layer and comprising an inorganic material, one portion of the second barrier layer making contact with one portion of the first barrier layer;
a circuit layer disposed on the second barrier layer and comprising a plurality of transistors;
a light-emitting layer disposed on the circuit layer and comprising a plurality of light-emitting diodes;
an encapsulation layer disposed on the light-emitting layer,
a processor;
a memory configured to store data; and
a power module configured to generate or supply power;
wherein a thickness of the one portion of the first barrier layer is smaller than a thickness of another portion of the first barrier layer not making contact with the second barrier layer.
